(19) United States
(12) Patent Application Publication
(10) Pub. No.: US 2024/0157600 A1
(43) Pub. Date: May 16, 2024

(54) PRE-PRESSED CERAMIC BODIES FOR FABRICATION OF FLUID DEVICES AND FLUID DEVICES PRODUCED

(71) Applicant: CORNING INCORPORATED, CORNING, NY (US)

(72) Inventors: Alexander Lee Cuno, Sayre, PA (US); Thierry Luc Alain Dannoux, Avon (FR); James Scott Sutherland, Painted Post, NY (US)

(21) Appl. No.: 18/283,898

(22) PCT Filed: Mar. 29, 2022
(86) PCT No.: PCT/US2022/022299

§ 371 Date: Sep. 25, 2023

Related U.S. Application Data
(60) Provisional application No. 63/167,732, filed on Mar. 30, 2021.

(51) Int. Cl. B28B 3/10; B28B 7/34

(52) U.S. Cl. CPC B28B 3/10; B28B 7/346

(57) ABSTRACT

A module and process for forming a ceramic fluidic module (300) that includes a unified closed-porosity ceramic body (200) and a tortuous fluid passage (P) that extends through the body (200). The body (200) has a first mean density within a first layer (222) that is greater than a second mean density within a second layer (226). The first and second layers (222, 226) are axially serially arranged between opposed major surfaces (228, 229) of the body (200). The fluid passage (P) adjoins the first layer (222) of the body (200). The process includes pressing a first volume of ceramic powder (120) to form a pre-pressed body (150). A passage mold (130) is then positioned on the pre-pressed body (150). The pre-pressed body (150) and the passage mold (130) are then covered with a second volume of ceramic powder (125). The body (150), the mold (130), and the second volume of ceramic powder (125) are then pressed to form a pressed body (160). The pressed body (160) is heated and sintered to form the ceramic fluidic module (300).

### CROSS-REFERENCE TO RELATED APPLICATIONS

This application claims the benefit of priority under 35 U.S.C. § 119 of U.S. Provisional Application No. 63/167,732, filed Mar. 30, 2021, the content of which is incorporated herein by reference in its entirety.

### FIELD OF THE DISCLOSURE

The disclosure relates to methods of fabrication of ceramic structures, and more particularly to methods of fabrication of high density, closed-porosity unified ceramic structures, particularly high density, closed-porosity unified silicon carbide fluid devices, with smooth-surfaced tortuous internal passages extending through or within the structures or devices and supported on higher density layers of the structures and devices, and to the structures or fluid devices themselves.

### BACKGROUND

Silicon carbide ceramic (SiC) is a desirable material for fluidic modules for flow chemistry production and/or laboratory work and for structures for other technical uses. SiC has relatively high thermal conductivity, which is useful in performing and controlling endothermic or exothermic reactions. SiC has good physical durability and thermal shock resistance. SiC also possesses extremely good chemical resistance. But these properties, combined with high hardness and abrasiveness, make the practical production of SiC structures with internal features, such as SiC flow modules with tortuous internal passages, challenging.

Flow reactors and other structures formed of SiC and other ceramics have been fabricated recently by this Applicant using a variation of the “lost-material” approach. In this approach, a positive passage mold is incorporated within a volume of binder-coated ceramic powder. The ceramic powder with the passage mold inside is then pressed to form a green ceramic body, which thereafter undergoes further processing, such a demolding, debinding, and sintering, to form a sintered ceramic body with one or more smooth-surfaced fluidic passages extending therethrough.

The existing process for fabricating passage molds involves silicone molding of molten mold material, followed by mold cooling, and a largely manual process for removing passage mold from the silicone mold master. The passage molds are very fragile, especially near narrow regions of the passage around functional geometry, such as mixers. In some cases, the passage mold can be broken or otherwise damaged during its removal from the silicone mold master. The passage mold can also be broken or otherwise damaged during handling and especially during transfer into the pressing die, in which the passage mold may be partially suspended as it is lowered into the die.

Accordingly, there is a need for methods that minimize the stresses on passage molds during processing. Also needed are methods to form passage mold features, such as channel structures and through vias, that simplify the fabrication process. It would be further advantageous to improve the alignment of the passage mold, both in the plane of the fluidic module for improved port alignment, and out of the plane of the fluidic module for improving support of the passage mold in the same plane at the same depth within the fluidic module.

### SUMMARY OF THE DISCLOSURE

According to some aspects of the present disclosure, a process for forming a ceramic fluidic module for a flow reactor includes pressing a first volume of a binder-coated ceramic powder to form a first pressed body, positioning on the first pressed body a positive passage mold of a passage, covering the first pressed body and the passage mold with a second volume of the binder-coated ceramic powder, pressing the second volume of binder-coated ceramic powder, the passage mold, and the first pressed body to form a second pressed body, heating the second pressed body to remove the passage mold, and sintering the second pressed body to form the ceramic fluidic module having the passage extending therethrough.

According to some additional aspects of the present disclosure, a fluidic module for a flow reactor includes a unified closed-porosity ceramic body having a first mean density disposed within a first layer that is greater than a second mean density disposed within a second layer, the first and second layers axially serially arranged between opposed major surfaces of the ceramic body, and a tortuous fluid passage extending through the ceramic body and adjoining the first layer of the ceramic body.

The disclosed methods and variations thereof allow the practical production of the SiC structures, such as SiC fluidic modules, having the desirable features mentioned above.

Additional features and advantages will be set forth in the detailed description which follows, and will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the disclosure and the appended claims.

The accompanying drawings are included to provide a further understanding of principles of the disclosure, and are incorporated in, and constitute a part of, this specification. The drawings illustrate one or more embodiment(s) and, together with the description, explain, by way of example, principles and operation of the disclosure. It is to be understood that various features of the disclosure disclosed in this specification and in the drawings can be used in any combinations. By way of non-limiting examples, the various features of the disclosure may be combined with one another according to the following embodiments.

### BRIEF DESCRIPTION OF THE DRAWINGS

The following is a description of the figures in the accompanying drawings. The figures are not necessarily to scale, and certain features and certain views of the figures may be shown exaggerated in scale or in schematic in the interest of clarity and conciseness.

In the drawings:

FIG. 1 is a diagrammatic plan view outline of a fluid passage of a type useful in fluid devices showing certain features of the fluid passage;

FIG. 2 is a perspective external view of an embodiment of a fluid device of the present disclosure;

FIG. 3 is a diagrammatic cross-sectional view of an embodiment of a fluid device of the present disclosure;

FIG. 4 is a diagrammatic cross-sectional view of an embodiment of a fluid device of the present disclosure, showing a fluid passage of the device disposed within an uppermost layer of a unified ceramic body having at least two layers each with respective densities;

FIG. 5 is a diagrammatic cross-sectional view of an embodiment of a fluid device of the present disclosure, showing a fluid passage of the device disposed within a lowermost layer of a unified ceramic body having at least two layers each with respective densities;

FIGS. 6A-6I are a stepwise series of cross-sectional representations of aspects of a method for producing a fluid device of the present disclosure, showing a first embodiment of a procedure for positioning a positive passage mold on a pre-pressed ceramic body;

FIG. 7 is a perspective view of a pre-pressed ceramic body supporting a positive passage mold;

FIG. 8 is a top view of the pre-pressed ceramic body and the positive passage mold of FIG. 5 placed in a pressing die;

FIGS. 9A-9C are a stepwise series of cross-sectional representations illustrating a second embodiment of a procedure for positioning a positive passage mold on a pre-pressed ceramic body;

FIGS. 10A-10D are a stepwise series of cross-sectional representations illustrating a third embodiment of a procedure for positioning a positive passage mold on a pre-pressed ceramic body;

FIG. 11 are images of a positive passage mold master and a corresponding passage mold that can be formed using the mold master each including a plurality of alignment features;

FIGS. 12A-12E are a stepwise series of cross-sectional representations illustrating a fourth embodiment of a procedure for positioning a positive passage mold on a pre-pressed ceramic body;

FIGS. 13A-13D are a stepwise series of cross-sectional representations illustrating a fifth embodiment of a procedure for positioning a positive passage mold on a pre-pressed ceramic body;

FIG. 14 is a cross-sectional representation illustrating a step of a sixth embodiment of a procedure for positioning a positive passage mold on a pre-pressed ceramic body;

FIG. 15 is a simplified cross-sectional representation of a tool used in the procedure of FIG. 14 with the tool depicted in a pressed state against a first volume of ceramic powder;

FIG. 16 is a simplified cross-sectional representation of the tool of FIG. 15 released from the pressed ceramic powder to expose the pre-pressed ceramic body;

FIGS. 17A-17C are a stepwise series of cross-sectional representations illustrating a continuation of the sixth embodiment of the procedure of FIG. 14;

FIGS. 18A-18C are a stepwise series of cross-sectional representations illustrating an embodiment of a procedure for coating portions of the embossed features formed from the procedure of FIGS. 14-16;

FIG. 19 is an images of a positive fluid passage mold reinforced by a plurality of pre-pressed ceramic inserts; and

FIG. 20 is a cross-sectional representation illustrating a step of (a seventh embodiment) of a procedure for positioning a positive passage mold on a pre-pressed ceramic body.

### DETAILED DESCRIPTION OF THE PREFERRED EMBODIMENTS

Additional features and advantages will be set forth in the detailed description which follows and will be apparent to those skilled in the art from the description or recognized by practicing the embodiments as described in the following description, together with the claims and appended drawings.

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

In this document, relational terms, such as first and second, top and bottom, and the like, are used solely to distinguish one entity or action from another entity or action, without necessarily requiring or implying any actual such relationship or order between such entities or actions.

Modifications of the disclosure will occur to those skilled in the art and to those who make or use the disclosure. Therefore, it is understood that the embodiments shown in the drawings and described above are merely for illustrative purposes and not intended to limit the scope of the disclosure, which is defined by the following claims, as interpreted according to the principles of patent law, including the doctrine of equivalents.

For purposes of this disclosure, the term “coupled” (in all forms: couple, coupling, coupled, etc.) generally means the joining of two components directly or indirectly to one another. Such joining may be stationary in nature or movable in nature. Such joining may be achieved with the two components and any additional intermediate members being integrally formed as a single unitary body with one another or with the two components. Such joining may be permanent in nature, or may be removable or releasable in nature, unless otherwise stated.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an endpoint of a range, the disclosure should be understood to include the specific value or endpoint referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

Directional terms as used herein—for example up, down, right, left, front, back, top, bottom, above, below, and the like—are made only with reference to the figures as drawn and are not intended to imply absolute orientation.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

As used herein, a “tortuous” passage refers to a passage having no line of sight directly through the passage and with a path of the passage having at least two differing radii of curvature, the path of the passage being defined mathematically and geometrically as a curve formed by successive geometric centers, along the passage, of successive minimum-area planar cross sections of the passage (that is, the angle of a given planar cross section is the angle which produces a minimum area of the planar cross section at the particular location along the passage) taken at arbitrarily closely spaced successive positions along the passage. Typical machining-based forming techniques are generally inadequate to form such a tortuous passage. Such passages may include a division or divisions of a passage into subpassages (with corresponding subpaths) and a recombination or recombinations of subpassages (and corresponding subpaths).

As used herein a “monolithic” ceramic structure of course does not imply zero inhomogeneities in the ceramic structure at all scales. A “monolithic” ceramic structure or a “monolithic” ceramic fluidic module, as the term “monolithic” is defined herein, refers to a ceramic structure or fluidic module, with one or more tortuous passages extending therethrough, in which no (other than the passage(s)) inhomogeneities, openings, or interconnected porosities are present in the ceramic structure having a length greater than the average perpendicular depth d of the one or more passages P from the external surface of the structure or module 300, as shown in FIG. 3. Providing such a monolithic ceramic structure or monolithic ceramic flow module helps ensure fluid tightness and good pressure resistance of a flow reactor fluidic module or similar product.

As used herein a “unified” ceramic body is a ceramic body in which the ceramic material of the ceramic body has two or more distinct mean densities with each mean density encompassed within a respective layer arranged serially with respect other layers in a depth direction between opposing major surfaces of the ceramic body, where grains within each layer have a continuous and uniform distribution through an entirety of the layer in any direction, and where grains at a boundary between adjacent layers grow into one another such that there is no mechanical seam or joint between the adjacent layers. As used herein a “closed-porosity” ceramic body is a ceramic body in which the ceramic material of the ceramic body exhibits a pore topology that is closed such that the pores or cells in the material are isolated or connected only with adjacent pores or cells and have no permeability to fluid.

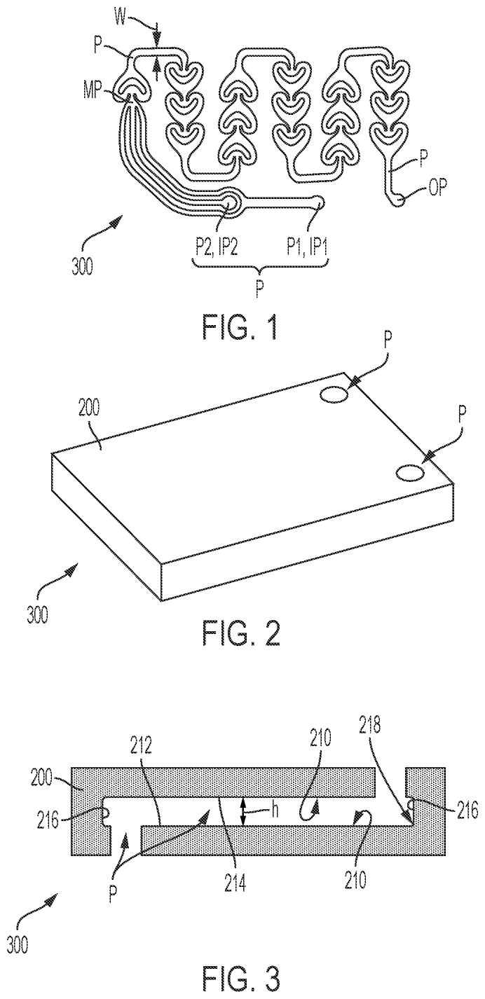

A fluidic device 300 for a flow reactor (not shown) is disclosed in FIGS. 1-3. The fluidic device 300 comprises a unified closed-porosity ceramic body 200 and a tortuous fluid passage P extending along a path through the ceramic body 200. The ceramic body 200 is formed from a ceramic material that includes any pressable powder that is held together by a binder and thermally processed to fuse the powder particles together into a structure. The ceramic material in some embodiments includes oxide ceramics, non-oxide ceramics, glass-ceramics, glass powders, metal powders, and other ceramics that enable high density, closed-porosity unified structures. Oxide ceramics are inorganic compounds of metallic (e.g., Al, Zr, Ti, Mg) or metalloid (Si) elements with oxygen. Oxides can be combined with nitrogen or carbon to form more complex oxynitride or oxycarbide ceramics. Non-oxide ceramics are inorganic, non-metallic materials and include carbides, nitrides, borides, silicides and others. Some examples of non-oxide ceramics that can be used for the ceramic body 200 include boron carbide (B₄C), boron nitride (BN), tungsten carbide (WC), titanium diboride (TiB₂), zirconium diboride (ZrB₂), molybdenum disilicide (MoSi₂), silicon carbide (SiC), silicon nitride (Si₃N₄), and sialons (silicon aluminum oxynitrides). The ceramic body 200 in the exemplary embodiment is formed from SiC.

The tortuous fluid passage P has an interior surface 210. The interior surface 210 has a surface roughness in the range of from 0.1 to 80 μm Ra, or 0.1 to 50, 0.1 to 40, 0.1 to 30, 0.1 to 20, 0.1 to 10, 0.1 to 5, or even 0.1 to 1 μm Ra, which is generally lower than SiC fluidic devices have previously achieved. The surface roughness of the interior surface 210 exists along any measured profile of the interior surface 210. For instance, when viewed in a planar cross section oriented normal to the path, the interior surface 210 defines an interior profile that completely encircles the path of the passage P. The surface roughness of the interior surface 210 exists along an entirety of the interior profile at every position along the path.

The tortuous fluid passage P, according to embodiments, comprises a floor 212 and a ceiling 214 separated by a height h and two opposing sidewalls 216 joining the floor 212 and the ceiling 214. The sidewalls are separated by a width w (FIG. 1) measured perpendicular to the height h and the direction along the passage (corresponding to the predominant flow direction when in use). Further, the width w is measured at a position corresponding to one-half of the height h. According to embodiments, the height h of the tortuous fluid passage P is in the range of from 0.1 to 20 mm, or from 0.2 to 15, or 0.3 to 12 mm. The width w of the tortuous fluid passage P can vary depending on the processes and/or reactions configured to take place along each position or region along the path.

According to embodiments, the interior surface 210 of the fluid passage P where the sidewalls 216 meet the floor 212 has a radius curvature (at reference 218) of greater than or equal to 0.1 mm, or greater than or equal to 0.3, or even greater than or equal to 0.6 mm, or 1 mm or 5 mm, 1 cm or 2 cm. The interior surface 210 of the fluid passage P, when viewed in a planar cross section oriented normal to the path, can have the same geometry and/or different geometries at different positions along the path. For instance, the interior surface 210 in some embodiments can have a cross-sectional shape in the form of a square, a rectangle, a circle, an oval, a stadium (i.e., a circle elongated at a mirror plane), and other shapes. The relative size of the same or different geometries can also vary along the path. The transition of sizes and/or geometries of the interior surface along the path are gradual to avoid introducing step-like structures within the fluid passage P. The interior surface 210 in embodiments preferably has a circular cross-sectional shape, which enables higher pressure resistance.

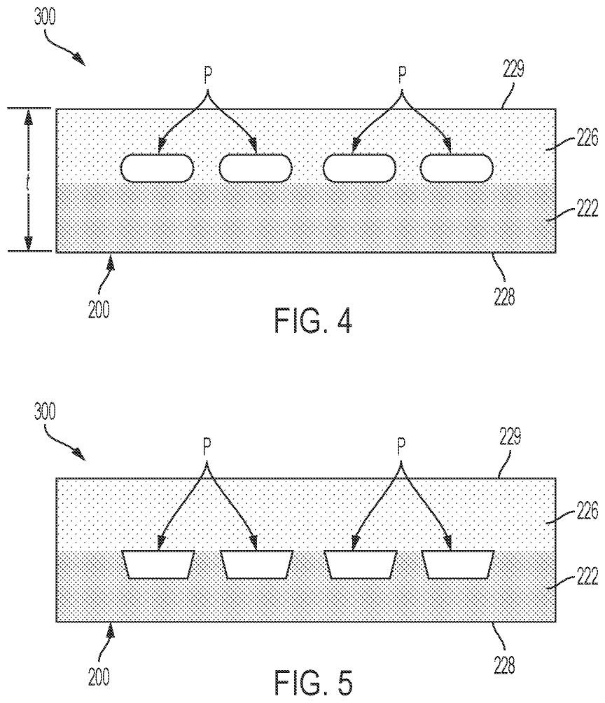

According to further embodiments, the ceramic body 200 of the fluidic device 300 has a grain structure with at least one discontinuity that is discernable at least in a direction between opposed major surfaces 228, 229 of the ceramic body. The at least one discontinuity can include a difference in grain size or shape and/or a difference in pore size or shape through the ceramic material of the ceramic body in the direction between the opposed major surfaces. The at least one discontinuity can also include a difference in mean density through the ceramic material in the direction between the opposed major surfaces. In embodiments, the discontinuity defines an interface between at least two layers of the ceramic body 200 as depicted in FIGS. 4 and 5. The interface in some embodiments is a planar interface that extends through an entirety of the ceramic body 200. In embodiments, it is possible to discern minor discontinuities in grain structure at the interface after firing, as during pre-pressing the granules are arranged along the top surface and possibly deformed so that they conform to the shape of the ram or piston that is pressing down on the pre-pressed powder.

The layers of the ceramic body 200 include a first layer 222 and a second layer 226 arranged serially along a direction of a thickness t of the ceramic body 200 between opposing first and second major surfaces 228, 229 of the ceramic body 200. The first layer 222 can also be referred to as a base layer or a bottom layer due to its position below the second layer during steps of the fabrication of the fluidic module 300 described later in this disclosure. Similarly, the second layer 226 can also be referred to as a cap layer or a top layer due to its position above the first layer during steps of the fabrication of the fluidic module 300. In embodiments in which the discontinuity relates to mean density, the ceramic material within the first layer 222 has a first mean density, and the ceramic material within the second layer 226 has a second mean density.

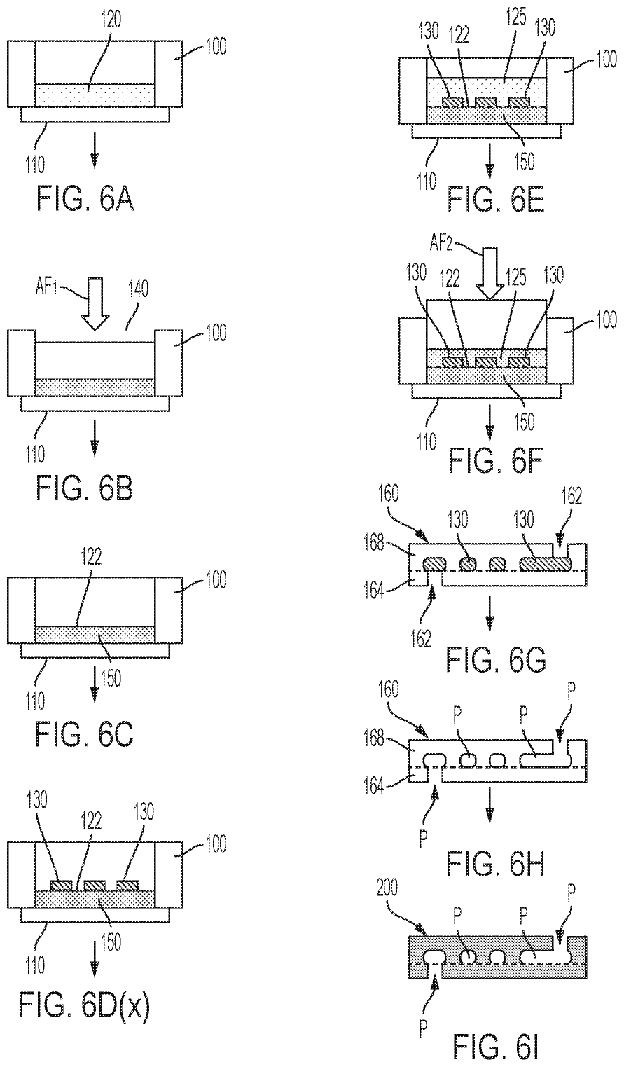

With reference to FIG. 4, the tortuous fluid passage P is disposed primarily within the second layer 226, and the tortuous fluid passage P adjoins the first layer 222 only at an interface between the first and second layers 222, 226. The interface is illustrated in FIG. 4 along a line in which the fill pattern of the first layer 222 abuts the different fill pattern of the second layer 226. The ceramic body 200 depicted in FIG. 4 corresponds with the process embodiments discussed below in which a passage mold is positioned/formed on a planar surface of a pre-pressed body (e.g., FIGS. 6-13).

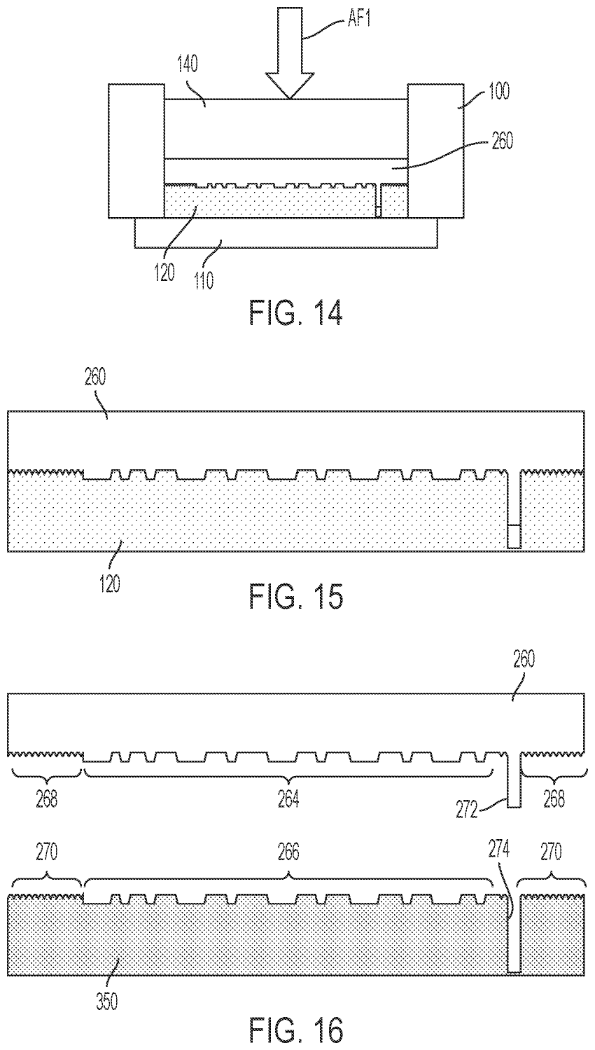

With reference to FIG. 5, the tortuous fluid passage P is disposed primarily within the first layer 222, and the tortuous fluid passage P adjoins the second layer 226 only at an interface between the first and second layers 222, 226. The interface is illustrated in FIG. 5 along a line in which the fill pattern of the first layer 222 abuts the different fill pattern of the second layer 226. The ceramic body 200 depicted in FIG. 5 corresponds with the process embodiments discussed below in which a passage mold is positioned/formed on embossed channels of a pre-pressed body (e.g., FIGS. 14-18).

The first and second mean densities within the first and second layer 222, 226 of the ceramic body 200 are each at least 95% of a theoretical maximum density of the ceramic material, or even of at least 96, 97, 98, or 99% of the theoretical maximum density. The theoretical maximum density (also known as maximum theoretical density, theoretical density, crystal density, or x-ray density) of a polycrystalline material, such as SiC, is the density of a perfect single crystal of the sintered material. Thus, the theoretical maximum density is the maximum attainable density for a given structural phase of the sintered material.

In the exemplary embodiment, the ceramic material is α-SiC with a hexagonal 6H structure. The theoretical maximum density of sintered SiC(6H) is 3.214±0.001 g/cm³. Munro, Ronald G., “Material Properties of a Sintered α-SiC,” Journal of Physical and Chemical Reference Data, 26, 1195 (1997). The ceramic material in other embodiments includes a different crystalline form of SiC or a different ceramic altogether. The theoretical maximum density of other crystalline forms of sintered SiC can differ from the theoretical maximum density of sintered SiC(6H), for example, within a range of 3.166 to 3.214 g/cm³. Similarly, the theoretical maximum density of other sintered ceramics also differs from that of sintered SiC(6H). As used herein, a “high density” ceramic body is a ceramic body in which the sintered ceramic material of the ceramic body has a density that of at least 95% of the theoretical maximum density of the ceramic material.

According to embodiments, the first mean density of the ceramic material within the first layer 222 is greater than the second mean density of the ceramic material within the second layer 226. The first mean density is 95.1% of the theoretical maximum density of the ceramic material, or even of at least 95.5%, 96%, 97%, 98%, 99%, 99.5%, or 99.9% of the theoretical maximum density. The corresponding second mean density is at least 95% of the theoretical maximum density of the ceramic material and can vary upwards therefrom up to just below the percent theoretical maximum of the first mean density.

According to embodiments, the ceramic body 200 of the fluidic device 300 has an open porosity of less than 1%, or even of less than 0.5%, 0.4%, 0.2% or 0.1% within each of the first and second layer 222, 226. The ceramic body 200 in embodiments has a closed porosity of less than 3%, or less than 1.5%, or even less than 0.5% within each of the first and second layers 222, 226. As used herein, a “closed-porosity” ceramic body is a ceramic body in which the ceramic material of the ceramic body exhibits a pore topology that is closed such that the pores or cells in the material are isolated or connected only with adjacent pores or cells and have no permeability to fluid.

According to still further embodiments, the ceramic body 200 of the device 300 has an internal pressure resistance under pressurized water testing of at least 50 bar, or even at least 100 bar, or 150 bar.

According to embodiments, a process for forming a fluid device for a flow reactor having one or more of these or other desirable properties is represented in FIG. 6. The process includes the step of (partially) filling a press enclosure (or die) 100, the press enclosure 100 being closed with a plug 110, with a first volume of binder-coated ceramic powder 120, as represented in the cross section of FIG. 6a. Next, a piston or ram 140 is inserted in the press enclosure 100 and a first uniaxial force AF₁ is applied from above to compress the first volume of ceramic powder 120 to form a first pressed body 150 (FIG. 6b). In the embodiment shown, a face of the ram 140 has a flat pressing surface so that a planar surface 122 is formed on the first pressed body 150 after pressing.

The first force AF₁ (also referred to as the “pre-press force” AF₁) applied by the ram 140 to form the first pressed body 150 (also referred to as the “pre-pressed body”) is less than the force applied for final pressing and is configured to generate a pressure of about 3-35 MPa on the first volume of ceramic powder 120. The first force AF₁ in some embodiments is 1-99% of the final pressing force, or 3-80%, 5-60%, or preferably 10-50% of the final pressing force. The pre-press force AF₁ is configured to ensure sufficient green strength for the pre-pressed body 150 though it can differ based on the type of ceramic powder and the source of the ceramic powder and even between lots of the same type of ceramic powder from the same source. The preferred powder is a ready-to-press (RTP) SiC powder that includes binder. If the pre-press force AF₁ is not high enough, the pre-pressed body 150 can crack during pressing and/or during handling after pressing. A pre-press force AF₁ that is too high, however, can hinder joining of the ceramic powder granules at the interface between the surface 122 of the pre-pressed body 150 and the subsequent poured ceramic powder 124 and can require higher final press forces to obtain adequate joining (FIGS. 5d and 5e, discussed below).

After the pre-pressed body 150 is formed, the ram 140 is retracted and the pre-pressed body 150 remains within the press enclosure 100 (FIG. 6c). Alternatively, the first pre-pressed body 150 can be ejected from the press enclosure 100, for example, by removing the plug 110 and forcing the pre-pressed body 150 out of the end of the press enclosure 100 using the ram 140. In embodiments in which the pre-pressed body 150 is ejected after pressing, the press enclosure is preferably smaller than a standard press enclosure within which final pressing takes place. For instance, the smaller press enclosure can be approximately 200 μm narrower in length and width than a standard press enclosure. The smaller press enclosure is used so that the pre-pressed body 150 fabricated in the reduced size press enclosure will fit easily into the slightly larger standard press enclosure for further processing as described herein.

The pre-pressed body 150 formed from the pressing sequence represented in FIGS. 6a-6c is solid and sufficiently joined to enable careful handling without damaging the body 150. The pre-pressed body 150 is still relatively fragile, however, with low green strength due to the lower pressing force. The density of the pre-pressed body 150 is also considerably lower than the density of a fully-pressed green fluidic module. In embodiments, the pre-pressed body 150 is a planar slab that has the approximately the same length and width as the green fully-pressed fluidic module.

The process next includes positioning on the pre-pressed body 150 a positive passage mold corresponding to the tortuous fluid passage P (FIG. 6dₓ). As shown in FIG. 6, the step label “d” includes the subscript “x” to denote multiple embodiments of this step. The embodiments include at least two variations in how the pre-pressed body 150 is formed during the pressing of the first volume of binder-coated ceramic powder 120. The embodiments also include at least six variations in how the positive passage mold is positioned on the pre-pressed body 150.

### Pre-Pressed Ceramic Bodies with Flat Surfaces as Carriers for Pre-Formed Passage Molds

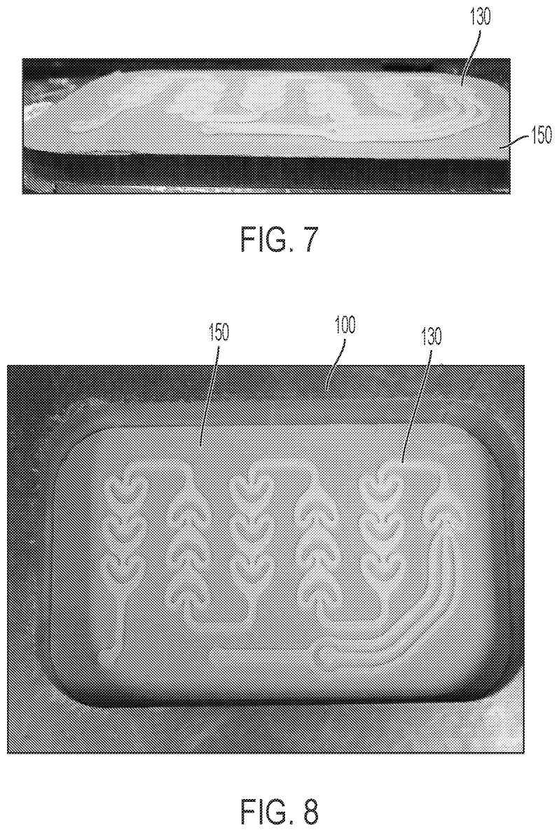

A first embodiment of positioning a positive passage mold on the pre-pressed body 150 is represented in FIG. 6d. The positive passage mold in this embodiment is a pre-formed positive passage mold 130 that is obtained separately from the process represented in FIG. 6. In embodiments, the passage mold 130 can be obtained (separately) by molding, machining, 3D printing, or other suitable forming techniques or combinations thereof. The material of the passage mold is desirably a relatively incompressible material. As shown in FIG. 6d, the pre-formed passage mold 130 is positioned directly on the surface 122 of the pre-pressed body 150. The positioning of the pre-formed passage mold 130 can take place with the pre-pressed body 150 ejected from the press enclosure 100 (FIG. 7) or with the pre-pressed body 150 remaining within the press enclosure 100 (FIG. 8). The pre-formed passage mold 130 is positioned on the surface 122 of the pre-pressed body so its fluid port regions IP, OP (FIG. 1) are in the correct locations for the (future drilled) fluidic port 162. Once positioned on the pre-pressed body 150, implements such as tweezer or alignment jigs can be used to align the fluidic port regions IP, OP, as needed.

If the pre-pressed body 150 was ejected from the press enclosure 100, the process also includes transporting the pre-pressed body 150 with the pre-formed passage mold 130 on the surface 122 back to the press enclosure 100 and inserting the pre-pressed body 150 into a standard press enclosure. The approximately 100 μm clearance around all sides of the pre-pressed body 150 obtained from use of the smaller press enclosure enable the pre-pressed body 150 to easily slide down into the standard press enclosure. In some embodiments, the standard press enclosure can be lowered over the pre-pressed body 150 with the pre-formed passage mold 130 on the surface 122.

The process next includes covering the pre-pressed body 150 and the pre-formed passage mold 130 with a second volume of the binder-coated ceramic powder 125 (FIG. 6e). A leveling tool (not shown) can be used to level the ceramic powder 125. The leveling of the ceramic powder 125 can help to create a flat exterior surface after subsequent pressing.

The process next includes inserting the ram 140 in the press enclosure 100 and applying a second uniaxial force AF₂ on the second volume of the binder-coated ceramic powder 125 to compress the pre-pressed body 150, the pre-formed passage mold 130, and the second volume of binder-coated ceramic powder 125 and form a second pressed body 160 (FIG. 6f). The second force AF₂ is configured to generate a maximum pressure of 35-40 MPa on the pre-pressed body 150, the pre-formed passage mold 130, and the second volume of binder-coated ceramic powder 125. The maximum pressure can vary in further embodiments in which the binder-coated powder and the passage mold are formed, respectively, from different materials. A reaction force or equal counteracting force AF₂ (not shown) is supplied at the plug 110 during this step.

Next, the second pressed body 160, now free from the press enclosure 100, is machined in selected locations, such as by drilling, to form holes or fluidic ports 162 extending from the outside of the second pressed body 160 to the passage mold 130 (FIG. 6g). Note that this is an optional step, because the holes can, in another alternative, be formed using a mold which includes the shape of the holes or fluidic ports as part of the mold. Also, as still another variation, drilling may be postponed and used as part of the de-molding step described below.

As shown in FIG. 6g, the second pressed body 160 has a first green layer 164 that corresponds to the (subsequently-pressed) first pressed body 150 and second green layer 168 that corresponds to the (subsequently-pressed) second volume of ceramic powder 125. The first and second green layers 164, 168 are joined after pressing with the second force AF₂ though respective green densities of the pressed ceramic powder within the layers will differ. In particular, the green density of the first green layer 164 is greater than the mean green density of the second layer 168 due to the pre-pressing of the body 150 in the prior steps represented in FIGS. 6a-6c. The dotted line between the green layers 164, 168 is shown merely to delineate the layers and not to indicate a seam or joint physically separating the layers.

Next, the second pressed body 160 is heated, preferably at a relatively high rate, such that the passage mold 130 is melted and removed from the second pressed body 160 by flowing out of the second pressed body 160, and/or by being blown and/or sucked out in addition. (FIG. 6h). In yet another alternative, this step can be divided into two parts, where first the second pressed body is heated (optionally while applying pressure to the exterior of the body via, for example, heated isostatic pressing), and then next, separately, the mold material can flow out of the body. It is also possible, in yet another alternative to de-mold the sample by heating the second pressed body 160 to melt mold, and only then drill holes or fluidic ports, while the body is still hot, allowing the mold material to flow out and complete demolding in this manner. The heating may be under partial vacuum, if desired.

Finally, the second pressed body 160 is de-bound to remove ceramic powder binder, and then fired (sintered) to densify and further solidify the second pressed body into a unified ceramic body 200. (FIGS. 4, 5, and 6i).

### Drilled Features in Pre-Pressed Ceramic Bodies with Flat Surfaces: Blind Holes for Aligning Pre-Formed Passage Molds

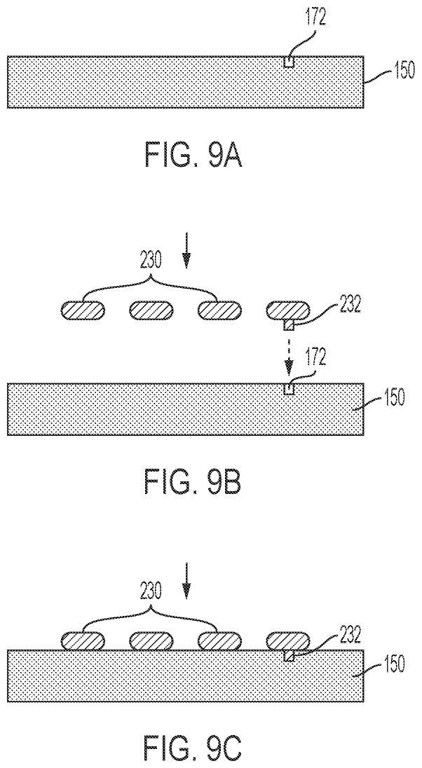

A second embodiment of positioning a positive passage mold on the pre-pressed body 150 is represented in FIG. 9. In this embodiment, at least one blind hole 172 is drilled into the pre-pressed body 150 to align at least one of fluid port region IP, OP of a pre-formed passage mold 230 on the pre-pressed body 150 (FIG. 9sa). FIG. 9b shows a cross-section view of the pre-formed passage mold 230 with at least one boss or protrusion 232 extending from one side of the passage mold 230 at a position corresponding to at least one of the fluid port regions IP, OP. The blind hole 172 can be drilled after the pre-pressed body 150 is removed from the press enclosure 100 or while the pre-pressed body 150 remains in the press enclosure. The blind hole 172 is located at a position where a through hole 162 (FIG. 6g) will be drilled through the second pressed body 160 after pressing. Alternatively, instead of a blind hole, a raised post, boss, ridge, or step can be pressed into the pre-pressed body 150, so that the raised press feature engages an interior or external feature on the passage mold 230, such as a hole or edge feature.

The blind hole 172 is sized to just receive the boss 232 of the passage mold 230, as shown in FIG. 9c, so that by pressing the boss 232 into the blind hole 172, the passage mold 230 is correctly positioned on the pre-pressed body 150 and secured in place during handing and transportation. It is important that the fluid port regions IP, OP of the passage mold 230 are centered on the drilled fluidic port interface holes 162. Other regions of the passage mold 230 can be displaced slightly from their target positions while not significantly influencing the fluid flow, heat transfer, or pressure resistance attributes of the fluidic device 300. After the passage mold 230 is positioned on the pre-pressed body 150 (FIG. 9), the steps represented in FIGS. 6e-6i of the process are carried out to form the fluidic device 300.

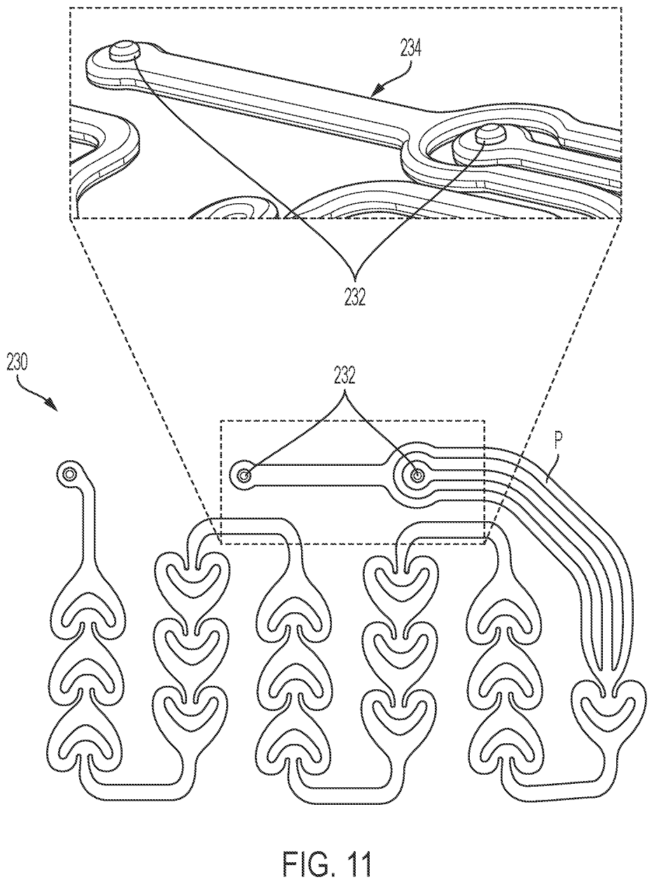

FIG. 11 shows images of a passage mold master 234 (top image) and the passage mold 230 (bottom image) that is formed using the mold master 234 to illustrate details of the design of the boss 232. As shown, the passage mold 230 and the mold master 234 each include a plurality of bosses 232. The bosses 232 in some embodiments are approximately 2.5 mm in diameter, 1 mm tall, and have 0.5 mm edge fillets. The mold master 234 in some embodiments is formed from engineering grade 7075-T651 aluminum.

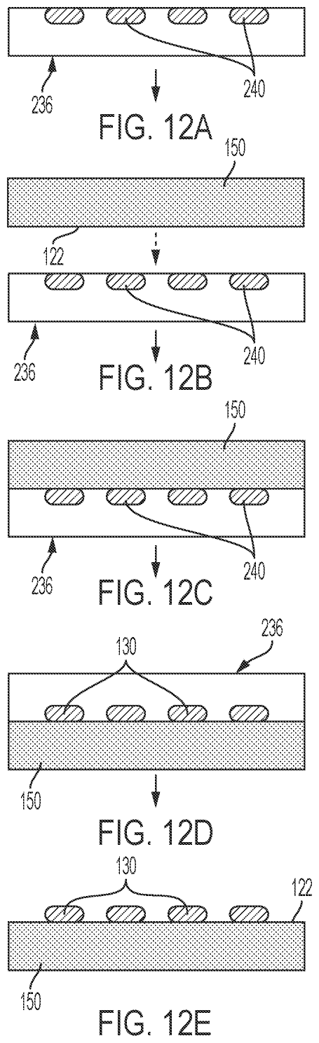

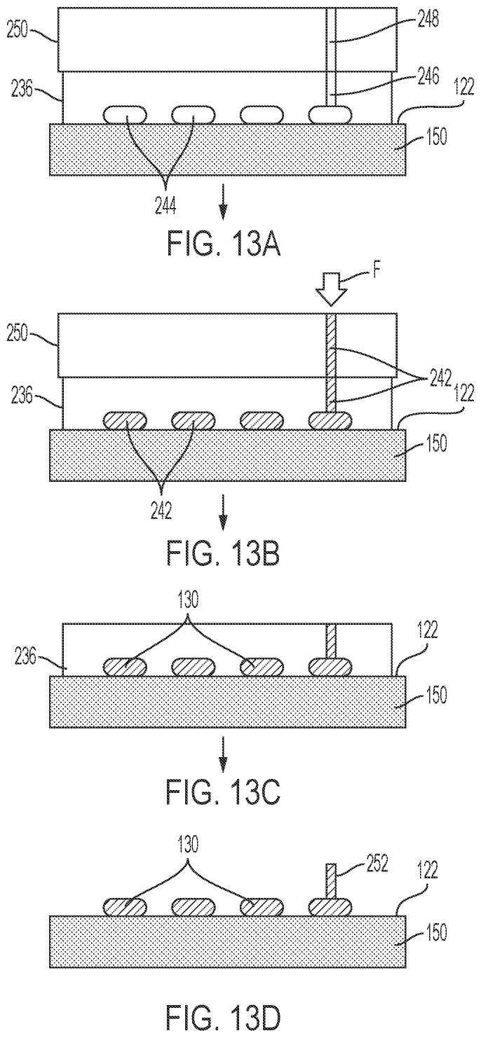

A silicone mold master 236 (FIGS. 12 and 13) is cast from the metal mold master 234. The passage mold 230 is cast in the silicone mold master 236. After the molten mold material cools, the passage mold 230 is removed from the silicone mold master 236. An upper radius lip (overhang) on the silicone mold master 236 can hinder removal of the passage mold 230 because more force and silicone mold master deformation is required to release the passage mold 230 from within the silicone mold master 236. However, the use of rounded channel walls increases the strength of the passage mold 230 enough to prevent the passage mold 230 from damage during removal.

The silicone mold master 236 demonstrates the ability of the passage mold 230 to replicate intricate features, such as the boss 232. Experiments have shown that the boss 232 of the passage mold 230 is inserted easily into drilled blind holes 172 in pre-pressed bodies 150.

### Drilled Features in Pre-Pressed Ceramic Bodies with Flat Surfaces: Through Holes for Aligning Pre-Formed Passage Molds and Forming Fluidic Ports

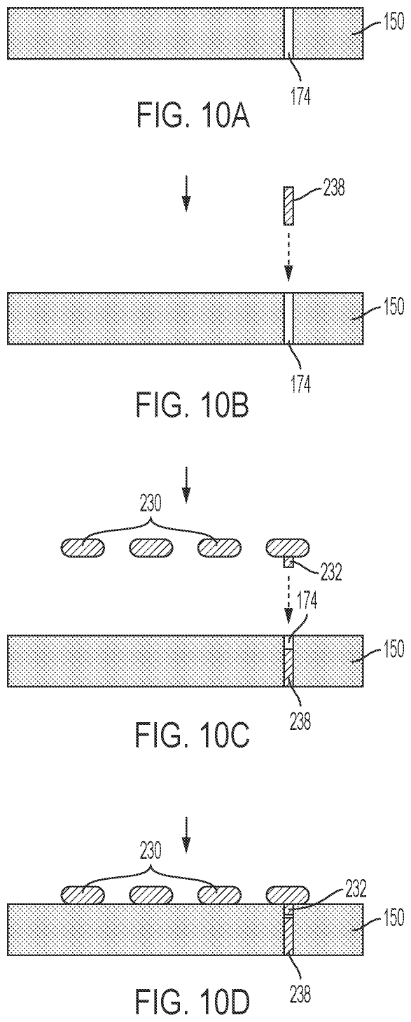

A third embodiment of positioning a positive passage mold on the pre-pressed body 150 is represented in FIG. 10. In this embodiment, at least one through holes is drilled in the pre-pressed body 150, either after the pre-pressed body 150 is removed from the press enclosure or while the pre-pressed body 150 remains in the press enclosure after pre-pressing (FIG. 10a). FIG. 10a shows a cross-section side view of the pre-pressed body 150 after the through hole 174 has been drilled through it at a position corresponding to at least one of the fluid port regions IP, OP. In FIG. 10b, a mold stub 238 is shown positioned over the through hole 174.

Once the mold stub 238 is inserted into the through hole, the passage mold 230 with the boss 232 is aligned over the through hole 174 (FIG. 10c). The boss 232 of the passage mold 230 is inserted into the through hole 174 so that a bottom surface of the boss 232 contacts a top surface the mold stub 238 (FIG. 10d). After the passage mold 230 is positioned on the pre-pressed body 150 (FIG. 10), the steps represented in FIGS. 6e-6i of the process are carried out to form the fluidic device 300. During final pressing (FIG. 6f), the boss 232 and the mold stub 238 fuse together, defining a fluidic port 162 that is properly aligned with the fluid port region IP, OP without the need for drilling after pressing. In an alternative approach, the (short) boss 232 can be replaced by a long boss (not shown) that simulates the mold stub 238. The long boss is inserted into the through hole 174 without the need to insert the mold stub 238.

### Forming Passage Molds on Pre-Pressed Ceramic Bodies with Flat Surfaces

A fourth embodiment of positioning a positive passage mold on the pre-pressed body 150 is represented in FIG. 12. In this embodiment, a passage mold 240 is molded directly on the surface 122 of the pre-pressed body 150. FIG. 12a shows a cross-section view of a silicone mold master 236 that has molten mold material 240 poured into channels of the mold master 236. While the mold material 240 is still molten, the pre-pressed body 150 is pressed against the silicone mold master 236 (FIG. 12b) so that the surface 122 of the pre-pressed body 150 contacts the molten mold material 240 (FIG. 12c). The temperature of the mold material 240 can be reduced so that it is soft enough to attached to the surface 122 of the pre-pressed body 150, but stiff enough to not wick into the pre-pressed body 150.

In some embodiments, after the mold material 240 cools and solidifies, the pre-pressed body 150 and the silicone mold master 236 are rotated 180 degrees so that the silicone mold master 236 is on supported on top of the pre-pressed body 150 (FIG. 10d). Next, the silicone mold master 236 is removed so that the passage mold 130 remains on the surface 122 of the pre-pressed body (FIG. 10e). The passage mold 130 is fused to the pre-pressed body 150 such that the pre-pressed body 150 retains the passage mold 130 thereon, preventing damage to the passage mold 130 during handling and insertion into the press enclosure. After the passage mold 130 is positioned on the pre-pressed body 150 (FIG. 12), the steps represented in FIGS. 6e-6i of the process are carried out to form the fluidic device 300.

A fifth embodiment of positioning a positive passage mold on the pre-pressed body 150 is represented in FIG. 13. In this embodiment, an empty silicone mold master 236 is positioned on the planar surface 122 of the pre-pressed body 150. The silicone mold master 236 is arranged such that cavities 244 of the silicone mold master 236 that define the passages P of the passage mold 130 are arranged to face the pre-pressed body 150 (FIG. 13a). The silicone mold master 236 can include a fluidic port hole 246 that extends vertically and mates with a feed tube 248 in a stiff mold plate 250 that is placed over the silicone mold master 236. A downward force F is applied on the mold plate 250 so that the silicone mold master 236 is forced into contact with the surface 122 of the pre-pressed body 150 (FIG. 13b). Molten mold material 242 is injected into the mold plate feed tube 248 so that it flows downward into the fluidic port 246 and eventually along the various channels that define the passages P of the passage mold 130 (FIG. 13b).

After the mold material 242 cools and solidifies, it joins to the surface 122 of the pre-pressed body 150. The mold plate 250 is removed from the silicone mold master 236 (FIG. 13c), and then the silicone mold master 263 is removed, leaving the passage mold 130 in contact with the pre-pressed body 150 (FIG. 13d). The silicone mold master 236 removal process can also leave a vertical fluidic port 252 of the passage mold 130 intact (FIG. 13d). This vertical fluidic port 252 can be used to make fluidic interconnections between fluidic channel layers. The passage mold 130 is fused to the pre-pressed body 150 such that the pre-pressed body 150 retains the passage mold 130 thereon, preventing damage to the passage mold 130 during handling and insertion into the press enclosure. After the passage mold 130 is positioned on the pre-pressed body 150 (FIG. 13), the steps represented in FIGS. 6e-6i of the process are carried out to form the fluidic device 300.

### Embossing Features into Pre-Pressed Ceramic Bodies to Position Passage Molds

A sixth embodiment of positioning a positive passage mold on the pre-pressed body 150 is represented in FIGS. 14-18. In this embodiment, instead of machining features into the pre-pressed body 150, a variety of features are formed by embossing during the pre-pressing process. FIG. 14 illustrates a step in which the ram 140 is inserted in the press enclosure 100 and a first uniaxial force AF₁ is applied from above to compress the first volume of ceramic powder 120. The ram 140 in this embodiment includes one or more (metal) tools 260 fitted to its end. The tool 260 is configured to emboss features in a pre-pressed body 350 during pressing of the first volume of binder-coated ceramic powder 120. FIG. 15 is a simplified cross-sectional representation of the tool 260 used in the procedure of FIG. 14 with the tool 260 depicted in a pressed state against the first volume of binder-coated ceramic powder 120. FIG. 16 is a simplified cross-sectional representation of the tool 260 used in the procedure of FIG. 14 with the tool 260 retracted to expose the pre-pressed body 350 with embossed features.

The tool 260 includes one or more positive features that form negative (inverse) features in the pre-pressed body 350 during pressing. As best illustrated in FIG. 16, the tool 260 includes positive channels 264 that are configured to form corresponding embossed channels 266 in the surface of the pre-pressed body 350 during pressing. The embossed channels 266 can serve as molds for in-situ casting of the passage mold in some embodiments. The tool 260 also includes positive texturing 268 that is configured to form corresponding embossed texturing 270 in the surface of the pre-pressed body 350 during pressing. The embossed texturing 270 is configured to improve granule knitting when the second volume of powder 125 is joined to the pre-pressed body 350 during pressing. The tool 260 also incudes one or more posts 272 that are configured to form corresponding through holes 274 in the pre-pressed body 350 during pressing. The through holes 274 in some embodiments are configured to form fluidic ports 162.

The embossing process in embodiments is carried out in a single pressing step or in multiple steps with the one or more (metal) tools 260 used to shape the surface and/or the body of the pre-pressed body 350. The flow of ceramic powder during pressing can be enhanced using ultrasonic vibration and/or and by applying the ceramic powder in layers. When the ceramic powder is applied in layers, coarse ceramic powders are used in the bottom layers and finer ceramic powders are used in the top layers. For example, the pre-pressed body 350 can undergo a first pressing using a portion of coarse ceramic powder, where the granules of the coarse ceramic powder are able to rearrange easily. The pre-pressed body 350 can then undergo a second pressing using a portion of fine ceramic powder layer, where the granules of the fine ceramic powder fill in gaps between the coarse granules, thereby forming a smooth, dense channel surface.

An advantage of the embossing process is that it enables fabrication of fluidic port interconnection channels in the same step as the surface channel features. With reference again to FIG. 16, the post 272 that extends from the tool 260 is configured to form a vertical channel 274 in the pre-pressed body 350. The post 272 can be tapered slightly to simplify its removal after pressing. Since the ceramic powder will compress vertically during pre-pressing, some embodiments may include a receiving hole in the bottom of the press enclosure that is positioned to receive the lower portion of the post 272 during pressing. Alternatively, the post 272 can be made shorter so that a bottom surface of the post 272 is located at or near the bottom surface of the pre-pressed body 350 during pressing. In this embodiment, the ceramic powder should be coarse enough to enable powder rearrangement late in the pressing process when the post 272 penetrates to the depth of the bottom of the pre-pressed body 150. In this embodiment, ultrasonic agitation of the ceramic powder may facilitate such late powder rearrangement.

FIG. 16 shows that the flat portion of the bottom surface of the tool 260 laterally away from channel features 246 includes positive texturing 268. The positive texturing 268 imprints a similar textured profile into the facing surface of the pre-pressed body 350. The embossed texturing 270 in the surface increases the surface area of the interface surface of the pre-pressed body 350. Such embossed texturing significantly improves the mechanical bond between the second volume of binder-coated ceramic powder 125 and the pre-pressed body 350 after final pressing. This improvement is thought to occur because the pre-pressing process orients ceramic powder granules along a flat plane when the bottom surface of the tool 260 is not textured. The oriented ceramic powder granules may not present enough surface area to bond and fuse with the more randomly oriented ceramic powder 125 that is poured over the pre-pressed body 350 prior to final pressing (FIG. 6e). The embossed texturing increases the bonding area. The embossed texturing also forms a bond between covering ceramic powders 125 and the pre-pressed body 350 along an angled interface, which can be stronger under application of tension forces working to separate the pre-pressed body 350 from the rest of the fluidic module in subsequent processing steps (e.g., debinding and firing).

A release material or film may be applied to the bottom surface of the tool 260 to simplify the removal of the tool 260 after pre-pressing. This application of release material can be important for areas of the tool 260 that include the positive texturing 268 since in these areas the ceramic powder can bond more effectively to the tool 268 after pressing due to the higher surface area at the interface. Some examples of release material include Saran wrap, LDPE (low-density polyethylene, LLDPE (linear low-density polyethylene), HDPE (high-density polyethylene), PET (Polyethylene Terephthalate), and PTFE (Polytetrafluoroethylene). Mold release sprays containing silicones or PTFE materials can also be used as the release material.

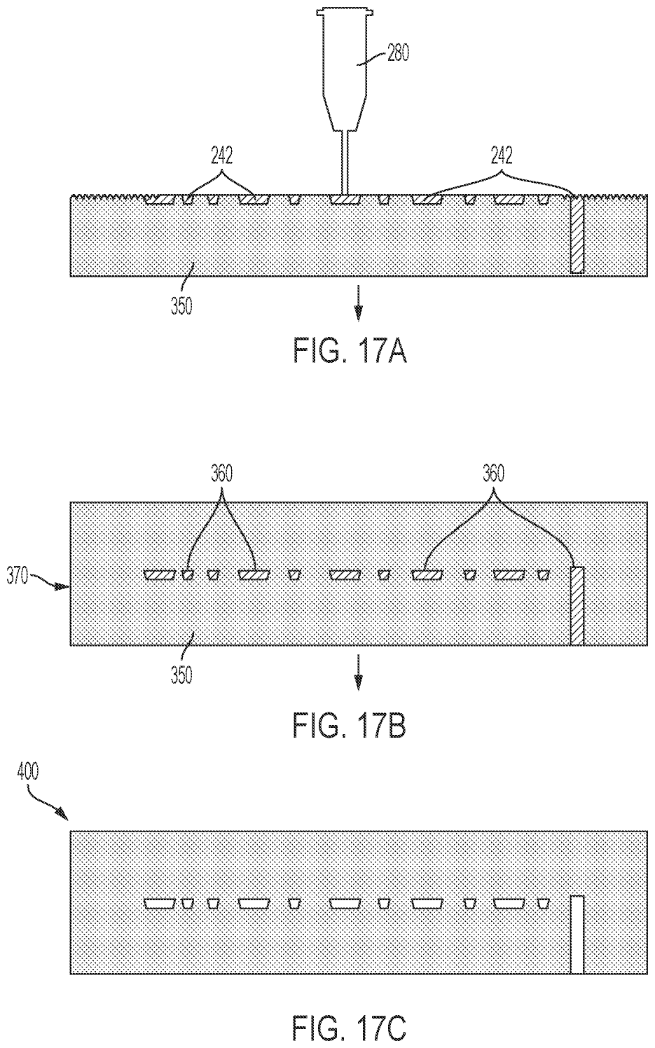

After pre-pressing, the pre-pressed body 350 can be removed from the press enclosure or alternatively it can remain in the press enclosure. In either case, a (heated) reservoir 280 can be used to fill the embossed channels 266 and through holes 274 with molten mold material 242 (FIG. 17a). The reservoir 280 can be traversed over the surface of the pre-pressed body 350, following the path of the embossed channels 266 as the molten mold material 242 is dispensed, using, for example, a CNC motion stage. This movement allows the molten mold material 242 to flow to fill the embossed channels 266 before cooling rapidly. Alternatively, the mold material 242 can be 3D-printed directly into the embossed channels 366 using a dedicated 3D printing machine (not shown).

The molten mold material 242 in some embodiments is dispensed into the embossed channels 266 of the pre-pressed body 350 so that the top of the molten mold material 242 lies below the surface of the pre-pressed body 350. The viscosity of the molten mold material can allow a curved meniscus profile at the top of the mold material, which helps to avoid the formation of sharp channel edges that can be stress concentrators during channel pressurization. Once the molten mold material 242 cools, it forms a passage mold 360 that conforms to the embossed channel 266 formed in the pre-pressed body 350.

In another filling approach, the passage mold is a pre-formed passage mold formed via molding or 3D printing or other process. The pre-formed passage mold is inserted into the embossed channels 266 of the pre-pressed body 350 at room temperature. Next, the entire pre-pressed body 350 can be heated to melt the material of the pre-formed passage mold and allow it to flow and contact the sidewalls of the embossed channels 266. Once the molten mold material 242 cools, it forms the passage mold 360.

After the passage mold 360 is positioned on the pre-pressed body 350 (FIG. 17a and alternatives), the pre-pressed body 350 and the passage mold 360 are covered with the second volume of binder-coated ceramic powder 125 and then the pre-pressed body 350, the passaged mold 360, and the ceramic powder 125 are fully pressed to form a second pressed body 370 (FIG. 17b). Next, the passage mold 360 is removed from the second pressed body 370 using a demolding process, such as press plate demolding, air bladder demolding, or isostatic demolding, and then the second pressed body 370 is debound and sintered to form the fluidic module 400 (FIG. 17c). The embossed pre-pressed slab approach can be used to fabricate a multilayer fluidic device with fluid passages extending through multiple planes of the fluid device spaced apart in the depth direction of the device. For example, after completion of a first layer, a second layer is processed on top of the first one and so on.

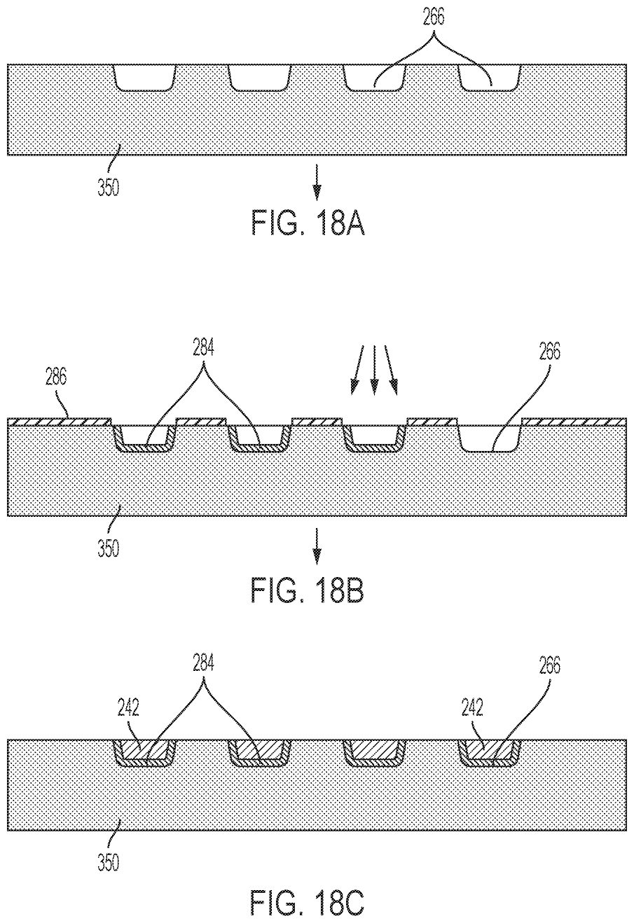

FIG. 18 is a stepwise series of cross-sectional representations illustrating an embodiment of a procedure for coating portions of the embossed features formed in the procedure of FIGS. 14-16. To prevent the molten mold material 242 from infiltrating the porous pressed ceramic powder that surrounds the embossed channels 266 after pre-pressing, a selective surface coating can be applied to the embossed channels 266 prior to mold material filling. FIG. 18a shows a cross-section of the pre-pressed body 350 immediately after the embossing represented in FIGS. 14-16. A thin surface coating 284 can be applied to the bottom and sidewalls of each embossed channel 266 using, for example, a spray coating process through a mask (FIG. 18b). Alternatively, the embossed channels 266 can be coated by an ink jet printing system that applies ink coatings only to the portions of the embossed channels that receive the molten mold material 242. The coating material can be a polymer, a higher melting temperature wax, a graphite coating, or any other material that impedes the flow of molten mold material 242 into the surrounding ceramic powder and that will not leave a residue after debinding and sintering. A cross-section of the embossed channels 266 after they are filled with molten mold material 242 is shown in FIG. 18c. Subsequent processing is identical to the process described above in this section.

### Passage Mold Materials

Numerous embodiments for positioning a passage mold on a pre-pressed ceramic body have been described. The material of the passage mold can be an organic material such as an organic thermoplastic. The mold material can include organic or inorganic particles suspended or otherwise distributed within the material as one way of decreasing expansion during heating/melting. As mentioned, the material of the passage mold is desirably a relatively incompressible material—specifically a material with low rebound after compression relative to the rebound of the pressed ceramic powder after compression. Mold materials loaded with particles can exhibit lower rebound after compression. Mold materials which are capable of some degree of non-elastic deformation under compression also naturally tend to have low rebound (e.g., materials with high loss modulus). Polymer substances with little or no cross-linking, for example, and/or materials with some local hardness or brittleness which enables localized fracturing or micro-fracturing upon compression can exhibit low rebound. Useful mold materials can include waxes with suspended particles such as carbon and/or inorganic particles, rosin containing waxes, high modulus brittle thermoplastics, and even organic solids suspended in organic fats such as cocoa powder in cocoa butter—or combinations of these. Low melting point metal alloys also may be useful as mold materials, particularly alloys having low or no expansion on melting.

### Pre-Pressed Ceramic Bodies as Inserts and Carriers

The pre-press ceramic body approach is useful in other areas of ceramic fluidic module design. For example, pre-pressed ceramic elements can be used to increase the density of ceramic powder in narrow regions between of a passage mold that do not fill well with ceramic powder during pressing. In another example, a passage mold can be made less fragile by reinforcing it with surrounding pre-pressed ceramic powder elements, and the combination of elements could be inserted into the pressed ceramic fluidic module at an appropriate layer or level. In yet another example, pre-pressed ceramic powder elements can be employed to fabricate very fine or fragile ceramic features, such as beams or thin walls that project into the channel path, or floating elements that are configured to be captive within internal cavities of the fluidic module to, for example, enhance mixing or operate as valve or flow direction elements.

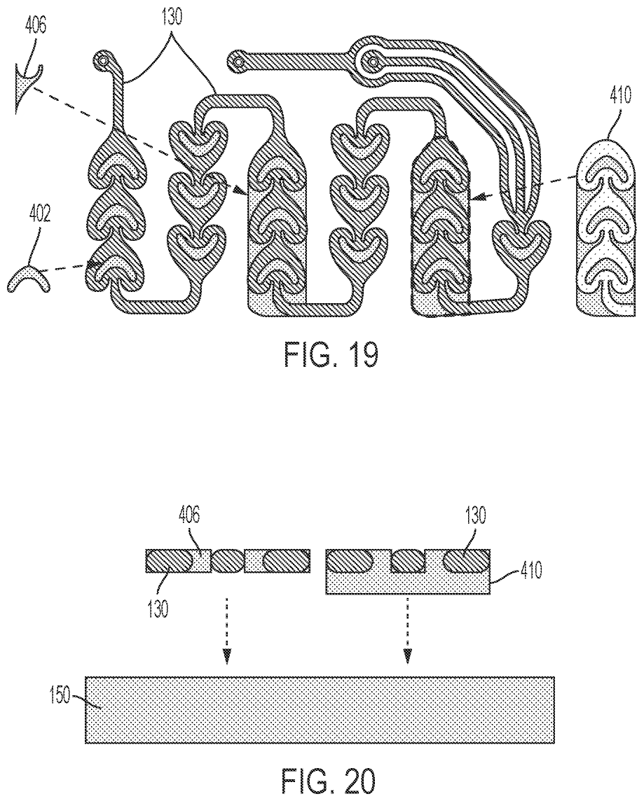

In many cases, channel cracks in pressed and sintered ceramic fluidic modules appear in narrow regions between passage molds that are not sufficiently densified during ceramic powder pressing. One solution is to pre-press the ceramic powder in the shape of these narrow regions, and then to insert the pre-pressed shapes into the passage mold prior to its insertion into the pressing die. FIG. 19 illustrates an example where a mixer region of the passage mold 130 is pre-pressed as small crescents 402 in a custom crescent-shape die. The crescents 402 are inserted into each mixer region, and then the passage mold 130 is placed in the die on a layer of ceramic powder. The ceramic powder layer can be a layer of loose powder or a pre-pressed body.

Once the passage mold 130 is placed on the ceramic powder layer, the passage mold 130 is covered with additional ceramic powder. The top and bottom surfaces of the pre-pressed crescent can be textured to improve joining with ceramic powder layers above and below the pre-pressed crescent. Similar pre-pressed parts can be fabricated for other narrow regions, such as a neck region 406 on either side of the mixer nozzle. These pre-pressed neck region inserts can be fabricated individually and applied to individual narrow areas. Pre-pressed parts can also be made to fill the narrow gaps between inlet channels towards the upper left corner in FIG. 19.

Pre-pressed carriers can also be fabricated to support portions of the passage mold 130 during handling, transportation, and pressing. FIG. 19 shows a pre-pressed carrier 410 on the right that is large enough to support three mixers. The pre-pressed carrier 410 includes raised features such as the narrow neck regions and the crescent regions. The passage mold 130 is pressed into the pre-pressed carrier, between the raised smile and neck regions. The pre-pressed carrier can be fabricated using one of the forming processes described above, including machining and embossing.

FIG. 20 is a cross-section view of a passage mold 130 with pre-pressed neck regions 406 placed on a pre-pressed body 150. The figure also shows a pre-pressed carrier 410 supporting a mixer of the passage mold 130 prior to its insertion into the pressing die. The pre-pressed carrier 410 can support one or more columns of mixers. The same approach can be applied along a longer portion of the passage mold 130, including along an entirety of the passage mold 130.

The devices disclosed and/or produced by the methods disclosed herein are generally useful in performing any process that involves mixing, separation including reactive separation, extraction, crystallization, precipitation, or otherwise processing fluids or mixtures of fluids, including multiphase mixtures of fluids—and including fluids or mixtures of fluids including multiphase mixtures of fluids that also contain solids—within a microstructure. The processing may include a physical process, a chemical reaction defined as a process that results in the interconversion of organic, inorganic, or both organic and inorganic species, a biochemical process, or any other form of processing. The following non-limiting list of reactions may be performed with the disclosed methods and/or devices: oxidation; reduction; substitution; elimination; addition; ligand exchange; metal exchange; and ion exchange. More specifically, reactions of any of the following non-limiting list may be performed with the disclosed methods and/or devices: polymerization; alkylation; dealkylation; nitration; peroxidation; sulfoxidation; epoxidation; ammoxidation; hydrogenation; dehydrogenation; organometallic reactions; precious metal chemistry/homogeneous catalyst reactions; carbonylation; thiocarbonylation; alkoxylation; halogenation; dehydrohalogenation; dehalogenation; hydroformylation; carboxylation; decarboxylation; amination; arylation; peptide coupling; aldol condensation; cyclocondensation; dehydrocyclization; esterification; amidation; heterocyclic synthesis; dehydration; alcoholysis; hydrolysis; ammonolysis; etherification; enzymatic synthesis; ketalization; saponification; isomerisation; quaternization; formylation; phase transfer reactions; silylations; nitrile synthesis; phosphorylation; ozonolysis; azide chemistry; metathesis; hydrosilylation; coupling reactions; and enzymatic reactions.

A first aspect of the present disclosure includes a process for forming a ceramic fluidic module for a flow reactor, comprising pressing a first volume of a binder-coated ceramic powder to form a first pressed body; positioning on the first pressed body a positive passage mold of a passage; covering the first pressed body and the passage mold with a second volume of the binder-coated ceramic powder; pressing the second volume of binder-coated ceramic powder, the passage mold, and the first pressed body to form a second pressed body; heating the second pressed body to remove the passage mold; and sintering the second pressed body to form the ceramic fluidic module having the passage extending therethrough.

A second aspect of the present disclosure includes a process according to the first aspect, wherein positioning a passage mold on the first pressed body includes positioning a pre-formed passage mold on the first pressed body.

A third aspect of the present disclosure includes a process according to the second aspect, wherein positioning a pre-formed passage mold on the first pressed body includes inserting a protrusion on the pre-formed passage mold into a hole defined in the first pressed body.

A fourth aspect of the present disclosure includes a process according to the third aspect, wherein the hole is a blind hole or a through hole.

A fifth aspect of the present disclosure includes a process according to the fourth aspect, further comprising inserting a mold stub into the through hole.

A sixth aspect of the present disclosure includes a process according to the first aspect, wherein positioning a passage mold on the first pressed body includes forming the passage mold on a surface of the first pressed body.

A seventh aspect of the present disclosure includes a process according to the sixth aspect, wherein forming the passage mold includes first filling a passage mold master with molten mold material and then pressing an open face of the passage mold master against the surface of the first pressed body.

An eighth aspect of the present disclosure includes a process according to the sixth aspect, wherein forming the passage mold includes first placing an open face of an empty passage mold master against the surface of the first pressed body and then filling the passage mold master with molten mold material.

A ninth aspect of the present disclosure includes a process according to the first aspect, wherein pressing a first volume of binder-coated ceramic powder includes forming at least one embossed channel in a surface of the first pressed body.

A tenth aspect of the present disclosure includes a process according to the ninth aspect, wherein positioning a passage mold on the first pressed body includes filling the at least one embossed channel with a molten mold material.

An eleventh aspect of the present disclosure includes a process according to the tenth aspect, further comprising, prior to filling the at least one embossed channel with the molten mold material, coating surfaces of the at least one embossed channel with a material configured to impede infiltration of the mold material into the first pressed body.

A twelfth aspect of the present disclosure includes a process according to the ninth aspect, wherein positioning a passage mold on the first pressed body includes positioning a pre-formed passage mold in the at least one embossed channel.

A thirteenth aspect of the present disclosure includes a process according to the twelfth aspect, further comprising heating the first pressed body to melt the pre-formed passage mold within the at least one embossed channel.

A fourteenth aspect of the present disclosure includes a process according to the first aspect, wherein the first volume of the binder-coated ceramic powder is pressed with a first force, wherein the second volume of the binder-coated ceramic powder, the passage mold, and the first pressed body are pressed with a second force, and wherein the first force is less than the second force.

A fifteenth aspect of the present disclosure includes a process according to the fourteenth aspect, wherein the first force is from 3% to 80% of the second force.

A sixteenth aspect of the present disclosure includes a fluidic module for a flow reactor comprising a unified closed-porosity ceramic body having a first mean density disposed within a first layer that is greater than a second mean density disposed within a second layer, the first and second layers axially serially arranged between opposed major surfaces of the ceramic body; and a tortuous fluid passage extending through the ceramic body and adjoining the first layer of the ceramic body.

A seventeenth aspect of the present disclosure includes a fluidic module according to the sixteenth aspect, wherein the tortuous fluid passage adjoins the first layer only at an interface between the first and second layers.

An eighteenth aspect of the present disclosure includes a fluidic module according to the sixteenth aspect, wherein the tortuous fluid passage adjoins the second layer only at an interface between the first and second layers.

A nineteenth aspect of the present disclosure includes a fluidic module according to the sixteenth aspect, wherein a material of the ceramic body is silicon carbide.

A twentieth aspect of the present disclosure includes a fluidic module for a flow reactor, comprising a unified closed-porosity ceramic body having a grain structure with at least one discontinuity disposed between opposed major surfaces of the ceramic body, the discontinuity defining an interface between first and second layers of the ceramic body, the first and second layers serially arranged between the opposed major surfaces; and a tortuous fluid passage extending through the ceramic body and adjoining the interface.

While exemplary embodiments and examples have been set forth for the purpose of illustration, the foregoing description is not intended in any way to limit the scope of disclosure and appended claims. Accordingly, variations and modifications may be made to the above-described embodiments and examples without departing substantially from the spirit and various principles of the disclosure. All such modifications and variations are intended to be included herein within the scope of this disclosure and protected by the following claims.

What is claimed is:

1. A process for forming a ceramic fluidic module for a flow reactor, comprising:
pressing a first volume of a binder-coated ceramic powder to form a first pressed body;
positioning on the first pressed body a positive passage mold of a passage;
covering the first pressed body and the passage mold with a second volume of the binder-coated ceramic powder;
pressing the second volume of binder-coated ceramic powder, the passage mold, and the first pressed body to form a second pressed body;
heating the second pressed body to remove the passage mold; and
sintering the second pressed body to form the ceramic fluidic module having the passage extending therethrough.

2. The process of claim 1, wherein positioning a passage mold on the first pressed body includes positioning a pre-formed passage mold on the first pressed body.

3. The process of claim 2, wherein positioning a pre-formed passage mold on the first pressed body includes inserting a protrusion on the pre-formed passage mold into a hole defined in the first pressed body.

4. The process of claim 3, wherein the hole is a blind hole or a through hole.

5. The process of claim 4, further comprising inserting a mold stub into the through hole.

6. The process of claim 1, wherein positioning a passage mold on the first pressed body includes forming the passage mold on a surface of the first pressed body.

7. The process of claim 6, wherein forming the passage mold includes first filling a passage mold master with molten mold material and then pressing an open face of the passage mold master against the surface of the first pressed body.

8. The process of claim 6, wherein forming the passage mold includes first placing an open face of an empty passage mold master against the surface of the first pressed body and then filling the passage mold master with molten mold material.

9. The process of claim 1, wherein pressing a first volume of binder-coated ceramic powder includes forming at least one embossed channel in a surface of the first pressed body.

10. The process of claim 9, wherein positioning a passage mold on the first pressed body includes filling the at least one embossed channel with a molten mold material.

11. The process of claim 10, further comprising, prior to filling the at least one embossed channel with the molten mold material, coating surfaces of the at least one embossed channel with a material configured to impede infiltration of the mold material into the first pressed body.

12. The process of claim 9, wherein positioning a passage mold on the first pressed body includes positioning a pre-formed passage mold in the at least one embossed channel.

13. The process of claim 12, further comprising heating the first pressed body to melt the pre-formed passage mold within the at least one embossed channel.

14. The process of claim 1, wherein the first volume of the binder-coated ceramic powder is pressed with a first force, wherein the second volume of the binder-coated ceramic powder, the passage mold, and the first pressed body are pressed with a second force, and wherein the first force is less than the second force.

15. The process of claim 14, wherein the first force is from 3% to 80% of the second force.

16. A fluidic module for a flow reactor, comprising:
a unified closed-porosity ceramic body having a first mean density disposed within a first layer that is greater than a second mean density disposed within a second layer, the first and second layers axially serially arranged between opposed major surfaces of the ceramic body; and
a tortuous fluid passage extending through the ceramic body and adjoining the first layer of the ceramic body.

17. The fluidic module of claim 16, wherein the tortuous fluid passage adjoins the first layer only at an interface between the first and second layers.

18. The fluidic module of claim 16, wherein the tortuous fluid passage adjoins the second layer only at an interface between the first and second layers.

19. The fluidic module of claim 16, wherein a material of the ceramic body is silicon carbide.

20. A fluidic module for a flow reactor, comprising:
a unified closed-porosity ceramic body having a grain structure with at least one discontinuity disposed between opposed major surfaces of the ceramic body, the discontinuity defining an interface between first and second layers of the ceramic body, the first and second layers serially arranged between the opposed major surfaces; and
a tortuous fluid passage extending through the ceramic body and adjoining the interface.
